(19) United States
(12) Patent Application Publication
(10) Pub. No.: US 2025/0309143 A1
(43) Pub. Date: Oct. 2, 2025

(54) HERMETIC LAYER ABOVE A DIE AND MOLD MATERIAL WITHIN A PACKAGE

(71) Applicant: INTEL CORPORATION, SANTA CLARA, CA (US)

(72) Inventors: Trianggono S. WIDODO, Hillsboro, OR (US); Nabankur DEB, Beaverton, OR (US); Xavier F. BRUN, Chandler, AZ (US); Md Mahbubul HASAN, Portland, OR (US)

(21) Appl. No.: 18/619,782

(22) Filed: Mar. 28, 2024

(51) Int. Cl. H01L 23/00; H01L 21/56; H01L 23/31; H01L 23/48; H01L 25/065

(52) U.S. Cl. CPC H01L 23/564; H01L 21/56; H01L 23/3185; H01L 23/481; H01L 24/16; H01L 25/0652; H01L 24/13; H01L 2224/13147; H01L 2224/16225

(57) ABSTRACT

Embodiments herein relate to systems, apparatuses, or processes for applying a hermetic layer within a semiconductor package to prevent or mitigate migration of moisture across the layer of material. In embodiments, the hermetic layer may include a nitride and may be a dielectric layer. The hermetic layer may be placed within a package on top of one or more dies that are sounded by filler material. The hermetic layer or a bonding layer on top of the hermetic layer may be used to facilitate fusion bonding of the package a silicon wafer. Other embodiments may be described and/or claimed.

### BACKGROUND

Continued reduction in the size of electronic devices, such as smart phones and ultrabooks, is a driving force for the development of high-quality, reduced-size system-in-package components.

### BRIEF DESCRIPTION OF THE DRAWINGS

FIG. 1 illustrates a cross-section side view of a legacy package that has a bonding layer on top of a plurality of dies surrounded by a filler material onto which a silicon wafer is fusion bonded.

FIGS. 2A-2B illustrates various diagrams and images that include a hermetic layer on a plurality of dies that are surrounded by a filler material, with a bonding layer on the hermetic layer that is fusion bonded with a silicon wafer, in accordance with various embodiments.

FIGS. 3A-3B illustrate a prospective view of a silicon wafer that is to be fusion bonded to another wafer that includes a plurality of packages, and a top-down cross section of a post fusion-bonded wafer, in accordance with various embodiments.

FIG. 4 illustrates a package with a hermetic layer on a plurality of dies that are surrounded by a filler material, with the hermetic layer fusion bonded with a silicon wafer, in accordance with various embodiments.

FIG. 5 illustrates a top-down cross-section view of a package with the layout of multiple dies separated by filler material with a hermetic layer on the dies in the filler material, in accordance with various embodiments.

FIGS. 6A-6G illustrate cross-section side views of various stages in a manufacturing process for creating a package that includes a hermetic layer on a plurality of dies that are surrounded by a filler material, with a bonding layer on the hermetic layer, in accordance with various embodiments.

FIGS. 7A-7B illustrate cross-section side views of various stages in a manufacturing process for creating a package that includes a hermetic layer on a plurality of dies that are surrounded by a filler material, with a portion of a silicon wafer fusion bonded to the hermetic layer, in accordance with various embodiments.

FIG. 8 illustrates an example of a process for manufacturing a package that includes a hermetic layer on a plurality of dies that are surrounded by a filler material, with a bonding layer on the hermetic layer, in accordance with various embodiments.

FIG. 9 schematically illustrates a computing device, in accordance with embodiments.

### DETAILED DESCRIPTION

Embodiments of the present disclosure may generally relate to systems, apparatus, techniques, and/or processes directed to applying a layer of material within a semiconductor package, where the layer of material may have hermetic properties, for example, to prevent or mitigate migration of moisture across the layer of material. In embodiments, the layer of material may include nitrogen and may include a nitride, for example SiNₓ or silicon nitride (Si₃N₄). In embodiments, the layer of material may be a dielectric layer. In embodiments, the layer of material may be referred to as a protective layer, or may be referred to as a hermetic layer.

In embodiments, the protective layer may be placed within a package above another layer in the package that includes one or more dies that are surrounded, at least in part or partially surrounded, by a filler material. In embodiments, this filler material may be referred to as a chip gap filler, a mold, or a molding compound. In embodiments, the filler material may include an epoxy used to bind filler particles that include but are not limited to silicon dioxide (SiO₂). In embodiments, the protective layer may come into contact with a portion of the one or more dies and a portion of the filler material. In this way, moisture that may be absorbed within the filler material during or after package assembly may be prevented from crossing the protective layer.

In embodiments, the nitride composition within the protective layer may allow it to conform to any uneven surfaces in the package layer that includes dies and filler material during application of the protective layer. In this way, the conformal application may serve to prevent voids from forming between the protective layer and the filler material, and as a result may reduce the number of delamination and/or failure points within the package.

In embodiments, a surface of the protective layer opposite the package layer that includes one or more dies and filler material may be substantially planar, or may be polished to become planar. As a result, another material may be fusion bonded to the surface of the protective layer. In embodiments, a silicon wafer may be fusion bonded to the protective layer.

In other embodiments, a bonding layer, which may include oxygen, may be placed on the surface of the protective layer, and another material, such as a silicon wafer or a layer of glass, may be fusion bonded to the bonding layer. In embodiments, this fusion bonding may include a dielectric to dielectric bonding technique. In other embodiments, other bonding or direct bonding techniques may be used.

In embodiments, in addition to providing a hermetic seal to prevent or mitigate moisture from penetrating the protective layer, the protective layer that includes a nitride may provide better adhesion with the filler material and the one or more dies, as well as with a bonding layer that includes oxide that may be on the protective layer. In addition, the protective layer, that includes a nitride, may be more conformal to the imperfections on the surface of the filler material or the one or more dies.

In embodiments, a layer of the protective layer that includes a nitride may be applied using low temperature deposition technique. In embodiments, this technique may include low temperature physical vapor deposition (PVD), chemical vapor deposition (CVD), atomic layer deposition (ALD), or spin coat. Subsequently, a bondable dielectric may be applied to the protective layer in preparation for fusion bonding. In embodiments, this bondable dielectric may be applied as a layer using different techniques and under more flexible conditions, such as a higher temperature. In embodiments, the bondable dielectric may be applied using PVD, CVD, or plasma enhanced chemical vapor deposition (PECVD) techniques.

In embodiments, the protective layer may be a dielectric. In embodiments, the protective layer may also serve as a stopping layer for planarization of the bonding dielectric layer deposited on top of it, for example using chemical mechanical polishing (CMP) or etching techniques.

In embodiments, the protective layer that includes nitride nominally provides a hermetic seal, but also promotes adhesion to a high quality deposition of the bonding dielectric layer, thus allowing better fusion while lowering the risk of delamination of the bonding dielectric to the die backside. In addition, the protective layer may also mitigate die cracking due to the different properties of the exposed materials, for example the material of the one or more dies and the filler material.

Furthermore, in embodiments, the protective layer that includes nitride enables the flexibility of using a number of different processing techniques for depositing the bonding dielectric layer at different and harsher processing conditions. This opens the possibility of using a higher quality bonding dielectric for the fusion bonding process deposited at optimized conditions. In embodiments, the higher quality bonding dielectric may include SiOx, SiCN, SiON and/or SiNx.

Additionally, in embodiments, with stacked die architectures with exposed silicon surfaces of the one or more dies and the filler material surrounding the dies, there is often dishing on the die backside after the mold grind process during manufacture. This dishing irregularity on the die backside can lead to uneven topography of a bonding dielectric when deposited directly on the die backside. As a result, this may lead to air gaps and voids that exist after the fusion bonding stage of the structural silicon wafer. In embodiments, the protective layer may act in part as a filler layer, filling in those dished areas using a conformal technique for deposition. As a result, there may be a more planar final bonding surface for the bonding layer to adhere to, which will result in fewer or no voids in the package after fusion bonding.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

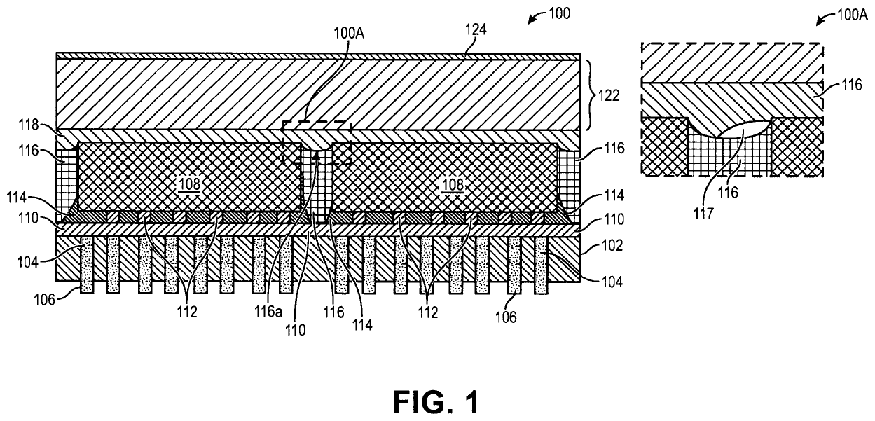

FIG. 1 illustrates a cross-section side view of a legacy package that has a bonding layer on top of a plurality of dies surrounded by a filler material onto which a silicon wafer is fusion bonded. Legacy package 100 includes a base die 102, which in some implementations may be a substrate. In implementations, the base die 102 may have one or more electrically conductive vias 104 extending through the base die 102 and electrically coupling with electrically conductive bumps 106 on a surface of the base die 102.

In implementations, a redistribution layer 110 may be on the base die 102, and may include bumps 112 that electrically couple with the one or more dies 108. In implementations, the bumps 112 may be electrically coupled with the electrically conductive vias 104 of the base die 102. It implementations, an underfill material 114 may be under the one or more dies 108. In implementations, a filler material 116, which may be a mold compound that includes epoxy and filler particles, may be placed between the one or more dies 108 and on top of the underfill material 114.

In implementations, a bonding layer 118, which may be referred to as a bondable dielectric layer, may be placed on top of the one or more dies 108 and on top of the filler material 116. Subsequent to placing the bonding layer 118, a layer 122 may be fusion bonded with the bonding layer 118. In implementations, the layer 122 may be a silicon layer, a layer of glass, another package component, a silicon layer, an interposer, or a structural element to support the processing of a plurality of legacy packages 100 on a wafer. In implementations, a backside metal layer 124 may be formed on a surface of the layer 122.

In implementations, the bonding layer 118 may include oxygen, for example it may include an oxide such as silicon oxide. In these legacy implementations, there may be a propensity for delamination at the bonding layer 118, which may be a dielectric, and the top of the one or more dies 108, particularly when the bonding layer 118 has a larger thickness, due to the lack of adhesion promotion within the a bonding layer 118.

Furthermore, the processing techniques, such as a planarization stage after the filler material 116 is applied, may result in dishing pattern 116a at a surface of the filler material 116. As shown in diagram 100A, using an oxide-rich bonding layer 118 has the propensity for dishing of the filler material 116 during processing. As a result, this may cause voids 117 in the filler material 116. These voids 117 may be referred to as air gaps. The voids 117 may form due to the non-conformal nature of the oxide-based bonding layer 118 when applied to the filler material 116. The voids 117 may then exist after the layer 122 is fusion-bonded to the bonding layer 118. Also, in legacy implementations, water or water vapor (not shown) that may be within the filler material 116 may migrate to the voids 117, and cause them to expand, or for additional voids (not shown) to form.

As a result, delamination between the filler material 116 and the bonding layer 118, as well as between the one or more dies 108 and the bonding layer 118 may begin to delaminate.

In addition, the bonding layer 118 above the one or more dies 108, particularly when a thickness of the bonding layer 118 increases, may encounter an increased lack of adhesion promotion due to coefficient of thermal expansion (CTE) deltas. This lack of adhesion promotion may also encourage delamination between the one or more dies 108 and the bonding layer 118.

Also, because particular dielectric deposition techniques may be required to be used for oxide-based material within the bonding layer 118 that involve lower temperatures, the risk of delamination and formation of voids 117 may be increased due to stress, CTE deltas, and defects on the bonding interface. This may be due to the difference in material between the silicon in the one or more dies 108 and the filler material 116.

In particular, filler material 116 may absorb moisture, and with thermal cycling during legacy package 100 operation, the voids 117 may grow due to moisture expansion. Over time, the layer 122 may begin to delaminate. The bonding layer 118, which may contain oxide, and the layer 122, which may contain oxide, may provide a solid fusion bonding, but the bonding layer 118 may not be effective as a moisture barrier.

In 3D heterogeneous packaging, especially for large form-factor products, the layer 122 may take the form of structural silicon, which may be in the form of a wafer. Structural silicon may provide mechanical benefits for package support once package components are thinned, and may facilitate co-planarity among the various heterogeneous components in the package. In addition to a co-planarity, the structural silicon may also provide good thermal benefit as an added benefit of the co-planarity in terms of heat dissipation to the mounted heat spreader.

Using structural silicon that is fusion bonded to a package may be applicable in a number of different architectures. For example, in architectures with exposed chip gap filler, such as epoxy mold, and silicon on the die 108 backside, choosing an optimal bonding layer 118, which may be referred to as a dielectric deposition layer, for fusion bonding to the structural silicon layer becomes very important. There may be a limited number of dielectric bonding films/layers with a good combination of material properties, such as good thermal conductivity and process conditions, such as deposition temperature. In addition, due to film stress and the coefficient of thermal expansion (CTE) differences of the bonding layer 118, silicon from the one or more dies 108, and the filler material 116, deposition of the bonding layer 118 can lead to delamination of the bonding layer 118.

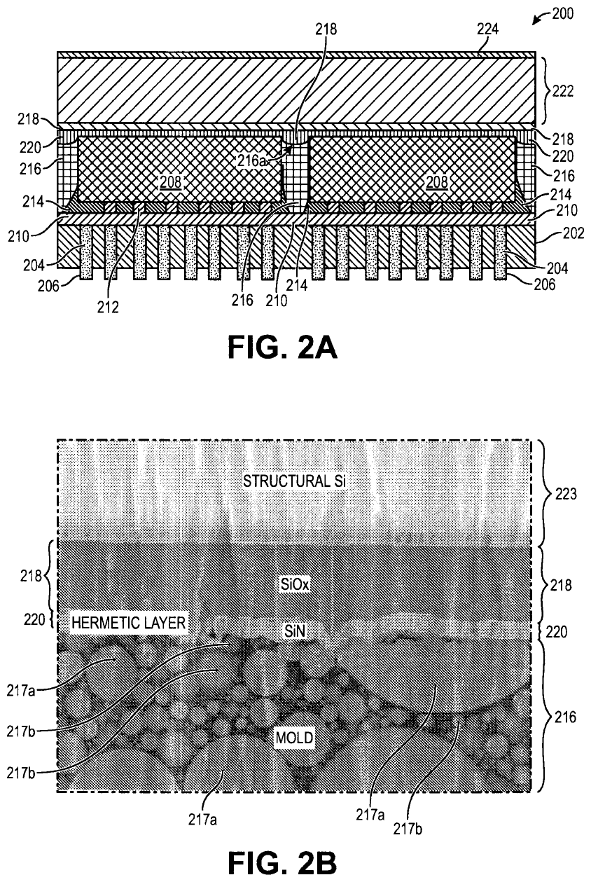

FIGS. 2A-2B illustrates various diagrams and images that include a hermetic layer on a plurality of dies that are surrounded by a filler material, with a bonding layer on the hermetic layer that is fusion bonded with a silicon wafer, in accordance with various embodiments. FIG. 2A illustrates a cross-section side view of a package 200, which may be similar to package 100 of FIG. 1. Package 200 includes a base die 202, which in embodiments may be a substrate, with one or more electrically conductive vias 204, which may be referred to as through-silicon vias (TSVs), extending through the base die 202 and electrically coupling with electrically conductive bumps 206 on a surface of the base die 202.

In embodiments, a redistribution layer (RDL) 210 may be on the base die 202, and may include bumps 212 to electrically couple, which may be also referred to as to conductively couple, with the one or more dies 208. In embodiments, the bumps 212 may include copper pillars or solder. In embodiments, the one or more dies 208 may be adjacent to each other. In embodiments, the bumps 212 may be electrically coupled with the electrically conductive vias 204 of the base die 202. In embodiments, the dies 208 may be direct bonded or hybrid bonded to the RDL 210 and electrically coupled with the RDL 210 without using bumps 212.

In embodiments, an underfill material 214 may be placed under the one or more dies 208. The base die 202, electrically conductive vias 204, electrically conductive bumps 206, dies 208, RDL 210, bumps 212, and underfill material 214 may be similar to base die 102, electrically conductive vias 104, electrically conductive bumps 106, dies 108, redistribution layer 110, bumps 112, and underfill material 114 of FIG. 1. In embodiments the underfill material 214 may fill in under dies 208 on the RDL 210 and between the bumps 212.

In embodiments, a filler material 216, which may be referred to as a mold material and which may be similar to filler material 116 of FIG. 1, may be placed around the dies 208. In embodiments, a protective layer 220, which may be referred to as a nitride layer, a hermetic layer, a dielectric layer, or a layer, may be placed on the filler material 116 and/or on the dies 208. In embodiments, the protective layer 220 may include nitrogen or a nitride material. In some embodiments, layer 220 comprises silicon nitride such that layer 220 comprises primarily silicon and nitrogen. When a structure such as layer 220 is described herein as comprising approximately one or more elements that means that the atomic composition of that structure in terms of either atomic percentages or atomic weight comprises primarily the disclosed element or elements while other elements may be present at lower percentages or weights. In embodiments, a bonding layer 218, which may be similar to bonding layer 118 of FIG. 1, may be placed on the protective layer 220. In some embodiments layer 118 comprises primarily silicon and oxygen. In embodiments, a layer 222, which may be similar to layer 122 of FIG. 1, may be fusion bonded onto the bonding layer 218. In embodiments, backside metal layer 224, which may be similar to backside metal layer 124 of FIG. 1, may be formed on the layer 222. In embodiments, the layer 222 may be a silicon wafer that may be used as a structural support. In some embodiments layer 222 comprises primarily silicon and less than 5% nitrogen and/or oxygen. In other words, in terms of elemental composition, the majority of atoms in layer 222 are silicon and less than 5% of the atoms in layer 222 are either nitrogen or oxygen or a combination of nitrogen and oxygen atoms.

In embodiments, the nitride material in the protective layer 220 may provide a hermetic barrier, and may also increase the conformal properties and increase adhesion of the protective layer 220 when applied to the filler material 216 and the one or more dies 208 as compared to the bonding layer 218. In embodiments, the protective layer 220 may conform to a greater extent than the bonding layer 218 to the uneven surfaces within the filler material 216, such as dishing pattern 216a which may be similar to dishing pattern 116a of FIG. 1. In addition, the protective layer 220 may serve as a better moisture barrier between the filler material 216 and the layer 222 as compared to just the bonding layer 218 alone.

In addition, by using a nitride-based protective layer 220, the planarity of a top of the protective layer 220, due to its conformal properties, may be increased, and therefore result in better adhesion with the bonding layer 218. Also, in embodiments, the bonding layer 218 composition and deposition techniques may be adjusted to achieve better fusion bonding while minimizing cracking or delamination of the die structures, for example one or more dies 208 and filler material 216, underneath the protective layer 220.

As a result, using the protective layer 220, which includes a nitride material or nitrogen, may provide for increased integrity of the overall package 200, and may result in a reduced risk of delamination of layers within the package. In implementations where layer 220 comprises silicon nitride, layer 220 may primarily comprise silicon and nitrogen. These features may be a result of nitride within the protective layer 220, for example silicon nitride. This is in contrast to a lack of nitride within the bonding layer 218, which may also include oxygen in the form of oxides. The existence of oxygen/oxides within the bonding layer 218, in addition to any hydrogen that may exist within the bonding layer 218, may result in water and/or water vapor be able to penetrate into the bonding layer 218. As a result, thermal cycling activity, where water may cycle between water vapor and liquid, will tend to cause the bonding layer 218 to delaminate if the protective layer 220 is not present.

In embodiments, initial protective layer 220, which may also be referred to as an adhesion promotion dielectric, may be deposited at a lower temperature than the epoxy filler material deposition temperature, subsequently followed by the bonding layer 218. In embodiments, the protective layer 220 may be a thin layer, for example less than 1.0 μm. In embodiments, both layers may be deposited using processes such as spin coat, PVD, CVD, or ALD. CSAM image (below) verifies the successful fusion bonding of this process architecture to a structural Si wafer. In embodiments, the protective layer 220 may include some oxygen and or some hydrogen. In embodiments, the amount of oxygen and/or hydrogen in the protective layer 220 may be 3% or less. In embodiments, the amount of oxygen and/or hydrogen comprises up to 3% of the protective layer 220 by cross-sectional area.

In embodiments, the layer 222 may be a glass layer. In these embodiments, the glass layer may be substantially all glass. The glass layer may be a solid mass comprising a glass material with an amorphous crystal structure where the solid glass core may also include various structures-such as vias, cavities, channels, or other features-that are filled with one or more other materials (e.g., metals, metal alloys, dielectric materials, etc.). As such, the glass layer 222 may be distinguished from, for example, the “prepreg” or “RF4” core of a Printed Circuit Board (PCB) substrate which typically comprises glass fibers embedded in a resinous organic material, such as an epoxy.

The glass layer may have any suitable dimensions. In a particular embodiment, the glass layer may have a thickness that is approximately 50 μm or greater. For example, the thickness of the glass layer may be between approximately 50 μm and approximately 1.4 mm. Though, smaller or larger thicknesses may also be used. The glass layer may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass layer (from an overhead plan view) may be between approximately 10 mm×10 mm and approximately 250 mm×250 mm. In an embodiment, the glass layer 222 may have a first side that is perpendicular or orthogonal to a second side. In other embodiments, the glass layer 222 may comprise a rectangular prism volume with sections (e.g., vias) removed and filled with other materials (e.g., metal, etc.).

The glass layer may comprise a single monolithic layer of glass. In other embodiments, the glass layer may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass layer may each have a thickness less than approximately 50 μm. For example, discrete layers of glass in the glass layer may have thicknesses between approximately 25 μm and approximately 50 μm. Though, discrete layers of glass may have larger or smaller thicknesses in some embodiments.

The glass layer may be any suitable glass formulation that has the necessary mechanical robustness and compatibility with semiconductor packaging manufacturing and assembly processes. For example, the glass layer may comprise aluminosilicate glass, borosilicate glass, alumino-borosilicate glass, silica, fused silica, or the like. In some embodiments, the glass layer may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, and Zn. More generally, the glass layer may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass layer may comprise at least 23 percent silicon (by weight) and at least 26 percent oxygen (by weight). In some embodiments, the glass layer may further comprise at least 5 percent aluminum (by weight).

FIG. 2B shows a cross-section side view of a scanning electron microscopy (SEM) image of a package that may be similar to package 200 of FIG. 2A. The filler material 216 as shown includes silicon dioxide particles 217a that are surrounded by an epoxy material 217b. On top of the filler material 216 is a protective layer 220. In embodiments, the protective layer 220 may include a nitride, such as silicon nitride (Si₃N₄). As shown, the top of the filler material 216 is very irregular, e.g. non-planar; however, the protective layer 220 due to its nitride component is able to highly conform to the top of the filler material 216, and as a result no or minimal voids may be formed.

The bonding layer 218 is able to conform to the top of the protective layer 220. Note that in legacy implementations, the bonding layer, without the nitride component, would be less likely to provide a good hermetic bonding layer.

After placement of the bonding layer 218, a structural silicon wafer 223, which may be similar to layer 222 of FIG. 2A, may be fusion bonded to the top of the bonding layer 218. In embodiments, the bonding layer 218, which may be referred to as a bonding dielectric, includes an oxide, and the structural silicon wafer 223 may also include an oxide. During the fusion bonding process, which may also be referred to as direct bonding, the structural silicon wafer 223 and the bonding layer 218 will be fused together.

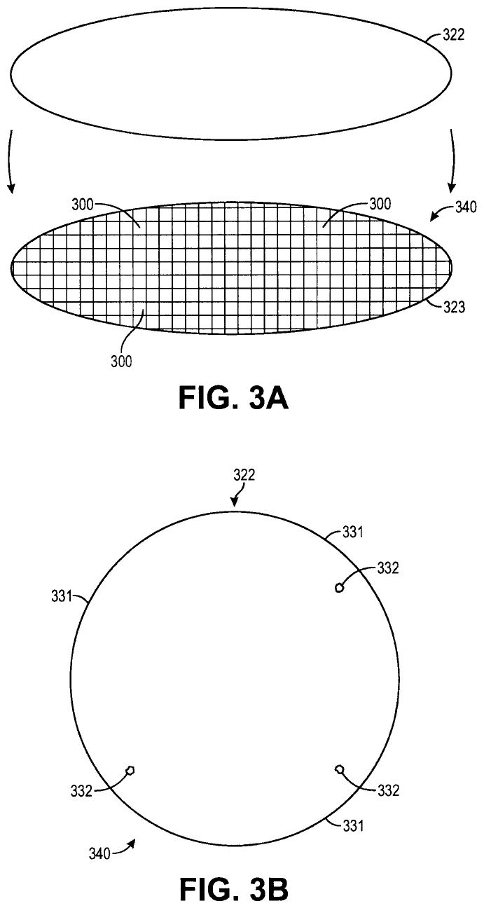

FIGS. 3A-3B illustrate a prospective view of a silicon wafer that is to be fusion bonded to another wafer that includes a plurality of packages, and a top-down cross section of a post fusion-bonded wafer, in accordance with various embodiments.

FIG. 3A shows wafer 322, which may be similar to layer 222 of FIG. 2A, or to structural silicon wafer 223 of FIG. 2B. Wafer 322 may be a circular wafer which may have a diameter of 800 mm. In other embodiments, the wafer 322 may be some other shape or may have some other dimension. In embodiments, a plurality of packages 300, each which may be similar to package 200 of FIG. 2A, may be on a surface of wafer 323 or may be otherwise integrated into the wafer 323 to form layer 340. In embodiments, the plurality of packages 300 may include one or more components found within package 200 of FIG. 2A.

In embodiments, a protective layer (not shown, but may be similar to protective layer 220 of FIGS. 2A-2B) may be placed on the layer 340, and a bonding layer (not shown, but may be similar to bonding layer 218 of FIGS. 2A-2B) may be placed on the protective layer. Subsequently, the wafer 322 may be fusion bonded to the protective layer (not shown) on the layer 340.

FIG. 3B shows a CSAM image of an example that shows the successful fusion bonding of this process architecture to a structural Si wafer. As shown, the wafer 322 has been fusion bonded on top of the layer 340. The area 331 shows void areas that appear underneath the edge of the wafer 322, and areas 332 show other void areas underneath the wafer 322. As seen, there are minimal void areas shown in FIG. 3B due to the use of the protective layer, such as protective layer 220 of FIG. 2A, which is highly conformal to the layer of filler material 216 of FIGS. 2A-2B, and which also has a high adhesion to the bonding layer 218 of FIGS. 2A-2B.

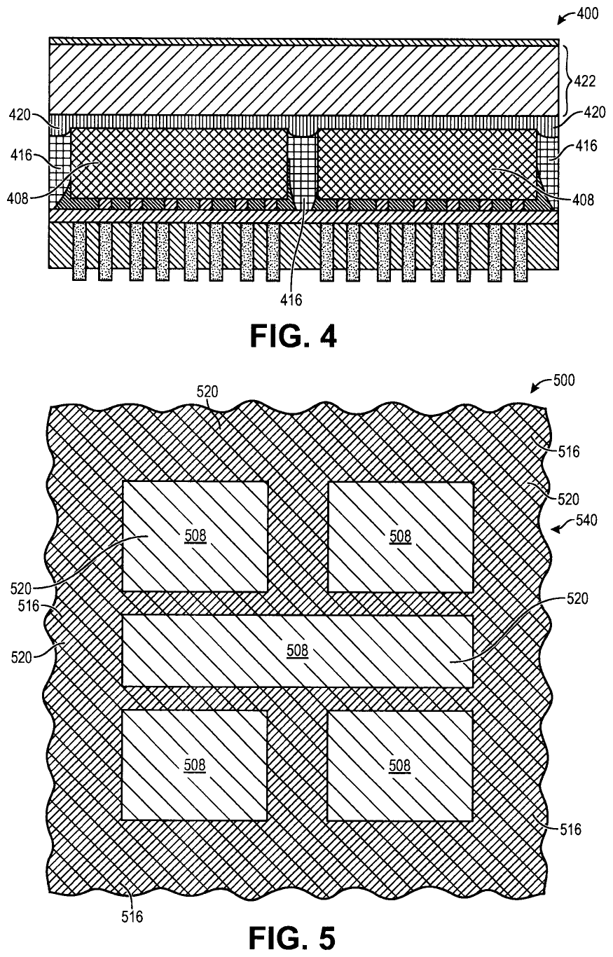

FIG. 4 illustrates a package with a hermetic layer on a plurality of dies that are surrounded by a filler material, with the hermetic layer fusion bonded with a silicon wafer, in accordance with various embodiments. Package 400, which may be similar to package 200 of FIG. 2A, includes layer 422 that may be above one or more top dies 408, and may be above filler material 416, which may be similar to layer 222, one or more top dies 208, and filler material 216 of FIG. 2A.

In embodiments, the protective layer 420, which may be similar to protective layer 220 of FIG. 2A, may be placed on top of the one or more top dies 408 and the filler material 416. In embodiments, a thickness of the protective layer 420 may be greater than a thickness of the protective layer 220 of FIG. 2A. In embodiments, the layer 422 may be directly on the protective layer 420, and may be directly fusion bonded to the protective layer 420.

In embodiments, the protective layer 420 may include a nitride, and the layer 422, which in embodiments may be a silicon layer or a structural silicon layer. In embodiments, the layer 422 may include an oxide, such as silicon dioxide, and may not include a nitride. In addition to providing a layer for fusion bonding, the protective layer 420 may be conformally applied to the top of the filler material 416 and the one or more top dies 408, similar to protective layer 220 of FIG. 2A. In addition, the protective layer 420 may serve as a hermetic layer to prevent or mitigate moisture transfer between the layer 422 and the one or more top dies 408 and the filler material 416.

FIG. 5 illustrates a top-down cross-section view of a package with the layout of multiple dies separated by filler material with a hermetic layer on the dies in the filler material, in accordance with various embodiments. Diagram 500, which may be similar to portions of packages 300 of FIG. 3A, shows a layer 540, which may be similar to a portion of layer 340 of FIG. 3A, that includes one or more dies 508 surrounded by filler material 516. In embodiments, the one or more dies 508 and the filler material 516 may be similar to the one or more dies 208 and the filler material 216 of FIG. 2A.

In embodiments, the dimension and the spacing of the one or more dies 508 may be varied. As a result, the height of the filler material 516 may be varied between the multiple dies 508. In particular, the filler material 516 between the multiple dies 508 may include different dishing patterns, such as dishing pattern 216a of FIG. 2A. In embodiments, a protective layer 520, which may be similar to protective layer 220 of FIG. 2A and which may include a nitride, may be conformally applied on top of the filler material 516 and the one or more dies 508.

After application of the protective layer 520, the protective layer 520 may be planarized, and then a layer (not shown but may be similar to layer 422 of FIG. 4), or a silicon wafer (not shown but may be similar to silicon wafer 322 of FIG. 3A), may be fusion bonded onto the protective layer 520. In other embodiments, a bonding layer (not shown, but may be similar to bonding layer 218 of FIG. 2A), may be placed on the protective layer 520 prior to fusion bonding.

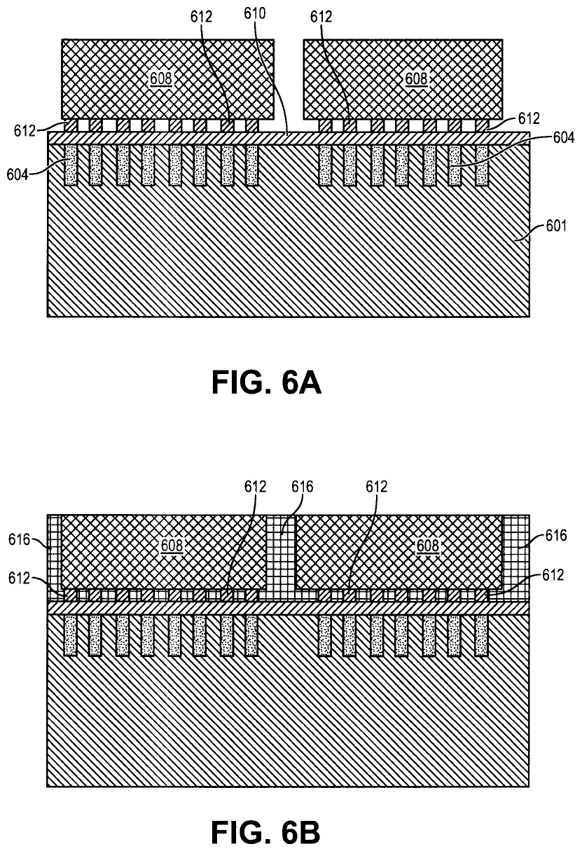

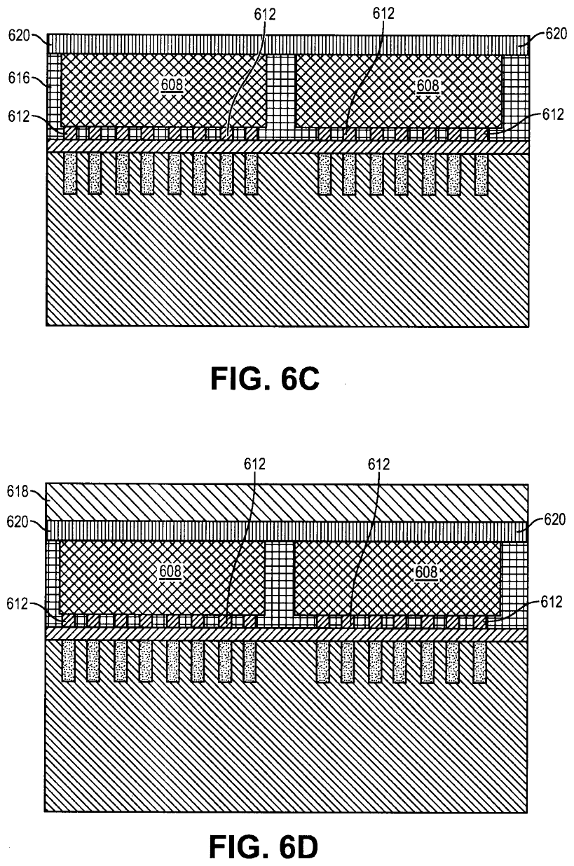

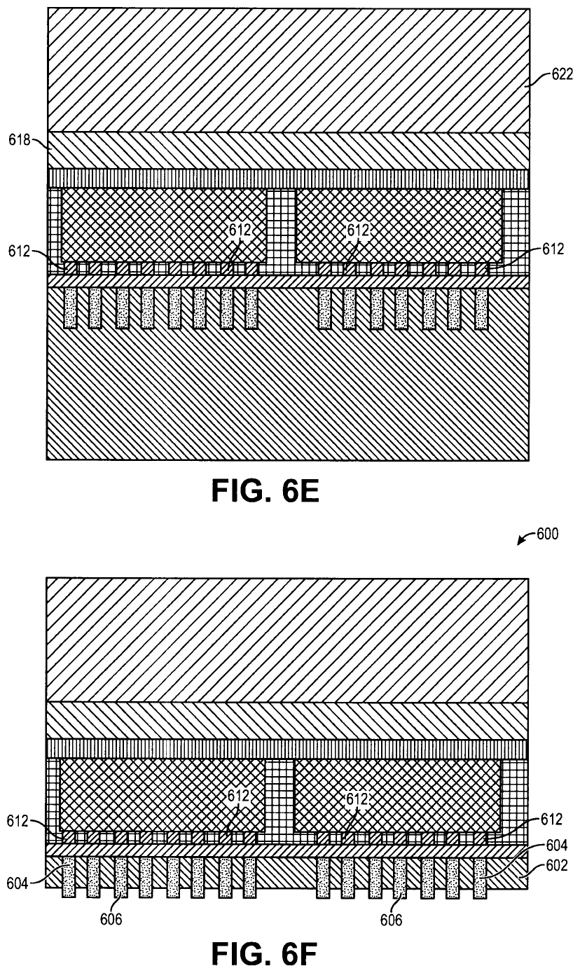

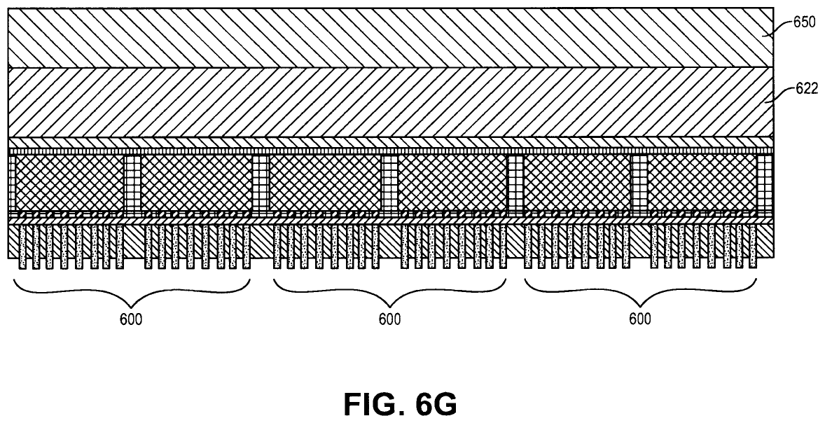

FIGS. 6A-6G illustrate cross-section side views of various stages in a manufacturing process for creating a package that includes a hermetic layer on a plurality of dies that are surrounded by a filler material, with a bonding layer on the hermetic layer, in accordance with various embodiments. FIG. 6A shows a cross-section side view of a stage in the manufacturing process where a base die 601, which may be similar to base die 202 of FIG. 2A, may be provided. The base die 601 may include a plurality of electrically conductive vias 604, which may be similar to electrically conductive vias 204 of FIG. 2A.

One or more dies 608 may be on the base die 601, and may be electrically coupled with the one or more electrically conductive vias 604 using bumps 612 which may be similar to bumps 212 FIG. 2A. In embodiments, an RDL 610, which may be similar to RDL 210 of FIG. 2A may be between the one or more dies 608 and the base die 601. In other embodiments, the base die 601 may be a substrate.

FIG. 6B shows a cross-section side view of a stage in the manufacturing process where a filler material 616, which may be similar to filler material 216 of FIG. 2A, is placed around the one or more dies 608. In embodiments, the filler material 216 may include particles that includes silicon that may be bonded together by an epoxy.

FIG. 6C shows a cross-section side view of a stage in the manufacturing process where a protective layer 620, which may be similar to protective layer 220 of FIG. 2A, may be placed on the filler material 616 and on the one or more dies 608. In embodiments, the filler material 616 and/or the one or more dies 608 may have undergone a planarization process. For example, a CMP process may be used prior to the application of the protective layer 620.

In embodiments, the protective layer 620 may be deposited or applied using PVD, CVD, ALD, or spin coat processes. In embodiments, the protective layer 620 may be deposited at a lower temperature, for example between 150° C. and 400° C. In embodiments, a thickness of the protective layer 620 may range from 100 nm to 1 μm. In embodiments, the protective layer 620 may form a hermetic seal to prevent or to mitigate the transmission of water or water vapor through the protective layer 620. In embodiments, this hermetic seal may be facilitated by the use of a nitride in the protective layer 620.

FIG. 6D shows a cross-section side view of a stage in the manufacturing process where a bonding layer 618, which may be similar to bonding layer 218 of FIG. 2A, may be placed on the protective layer 620. In embodiments, the bonding layer 618 may be referred to as a bonding dielectric, and may include either a nitride, such as silicon nitride, or may include an oxide, such as silicon oxide. In embodiments, the bonding layer 618 made be deposited using CVD, PVD, or ALD techniques. In embodiments, a top surface of the bonding layer 618 may be planarized in order to meet a particular thickness, or to meet a particular roughness in preparation for fusion bonding as discussed below.

FIG. 6E shows a cross-section side view of a stage in the manufacturing process where an layer 622, which may be similar to layer 222 of FIG. 2A, may be fusion bonded with the bonding layer 618. In embodiments, the layer 622 may be a dielectric material, or may be a wafer that may include silicon. In embodiments, the layer 622 may be a structural silicon wafer. In embodiments, the layer 622 may act as a permanent carrier.

FIG. 6F shows a cross-section side view of a stage in the manufacturing process where the base die 601 of FIG. 6A has been thinned to create base die 602. In embodiments, the thinning may be accomplished using a grinding process, and may be referred to as a through silicon via (TSV) reveal. In embodiments, one or more of the electrically conductive vias 604 may be exposed at the bottom of the base die 602. In embodiments, after thinning, bumps 606, which may be similar to bumps 206 of FIG. 2A, may be applied to physically and/or electrically couple with the base die 602. In embodiments, package 600 of FIG. 6F may be similar to one of the plurality of packages 300 of FIG. 3A.

FIG. 6G shows a cross-section side view of a stage in the manufacturing process where a ring frame 650 may be attached to the top of the layer 622. As shown, there may be a plurality of packages 600, as shown with respect to FIG. 6F, that are hybrid bonded to the layer 622. In embodiments, the ring frame 650 may be used to support the singulation of the packages 600. In embodiments, the ring frame 650 may be referred to as dicing tape.

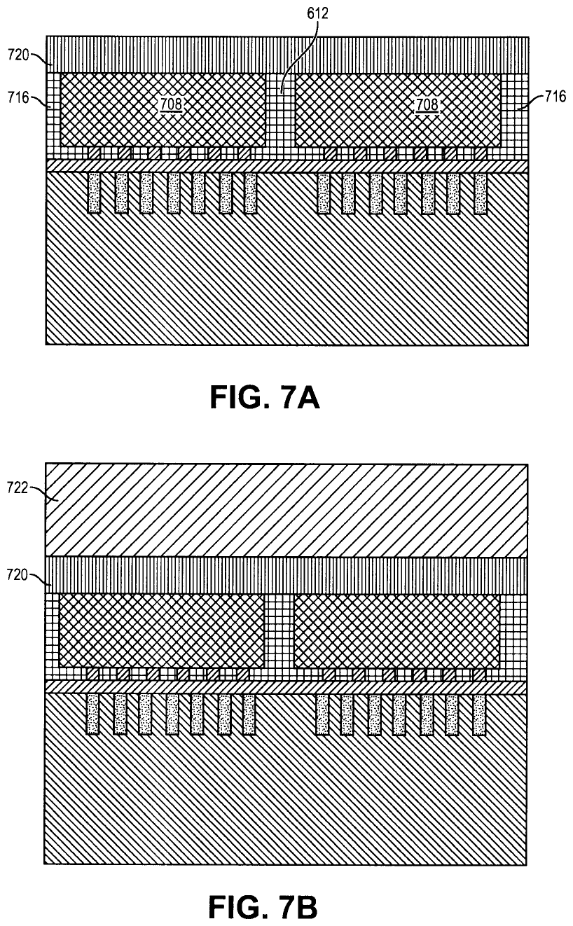

FIGS. 7A-7B illustrate cross-section side views of various stages in a manufacturing process for creating a package that includes a hermetic layer on a plurality of dies that are surrounded by a filler material, with a portion of a silicon wafer fusion bonded to the hermetic layer, in accordance with various embodiments. FIG. 7A shows a cross-section side view of a stage in the manufacturing process, which may be similar to FIG. 6C, where a protective layer 720, which may be similar to protective layer 620 of FIG. 6C or to protective layer 220 of FIG. 2A, may be placed on filler material 716 that surrounds one or more dies 708, which may be similar to filler material 216 and one or more dies 208 of FIG. 2A.

In embodiments, the protective layer 720 may be applied using a PVD, CVD, ALD, or spin coat process. In embodiments, the protective layer 720 may be used as a fusion bonding layer, and as a result the protective layer 720 may be thicker than the protective layer 620 of FIG. 6C. In embodiments, the protective layer 720 may include a nitride, such as silicon nitride.

FIG. 7B shows a cross-section side view of a stage in the manufacturing process where an layer 722 is fusion bonded to the protective layer 720. In embodiments, the layer 722 may be a layer of dielectric, may be a silicon layer, or may be a portion of a silicon wafer that is fusion bonded to the protective layer 720. In embodiments, the layer 722 may be a silicon structural wafer. Manufacturing stages subsequent to the stage shown in FIG. 7B may be performed that are similar to those shown with respect to FIGS. 6E-6G.

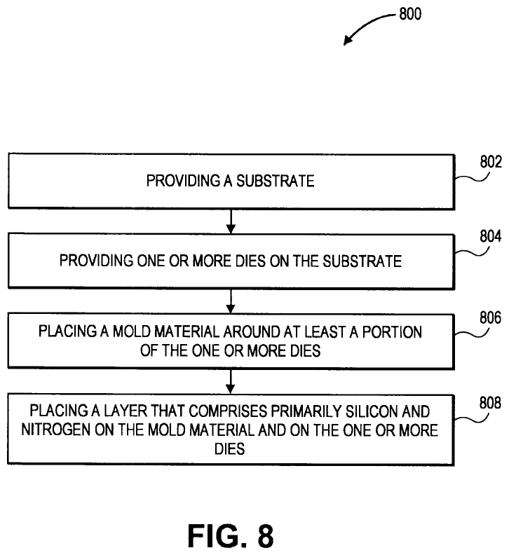

FIG. 8 illustrates an example of a process for manufacturing a package that includes a hermetic layer on a plurality of dies that are surrounded by a filler material, with a bonding layer on the hermetic layer, in accordance with various embodiments. In embodiments, process 800 may be performed using the tools, techniques, apparatus, systems, or processes described herein, and in particular with respect to FIGS. 1-7B.

At block 802, the process may include providing a substrate. In embodiments, the substrate may be similar to base die 202 of FIG. 2A or base die 602 of FIG. 6F. In other embodiments, the substrate may be similar to some other structure that may be part of a semiconductor package.

At block 804, the process may further include providing one or more dies on the substrate. In embodiments, the one or more dies may be similar to one or more dies 208 of FIG. 2A, one or more dies 408 of FIG. 4, one or more dies 508 of FIG. 5, one or more dies 608 of FIGS. 6A-6G, or one or more dies 708 of FIGS. 7A-7B.

At block 806, the process may further include placing a mold material around at least a portion of the one or more dies. In embodiments, mold material may be similar to filler material 216 of FIGS. 2A-2B, filler material 416 of FIG. 4, filler material 516 of FIG. 5, filler material 616 of FIGS. 6A-6G, or filler material 716 of FIGS. 7A-7B.

At block 808, the process may further include placing a layer that comprises primarily silicon and nitrogen on the mold material and the one or more dies. In embodiments, the layer may be similar to the protective layer 220 of FIGS. 2A-2B, layer 420 of FIG. 4, layer 520 of FIG. 5, layer 620 of FIGS. 6C-6G, or layer 720 of FIGS. 7A-7B.

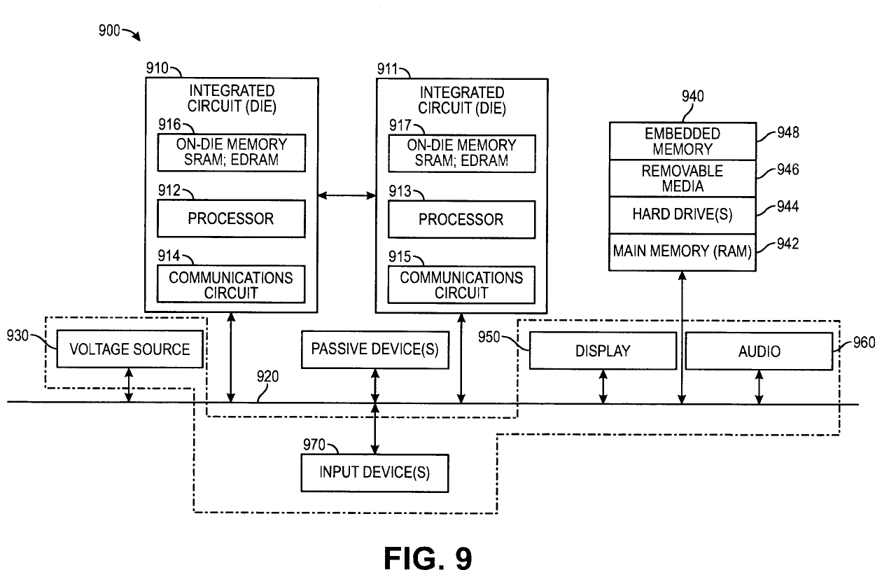

FIG. 9 is a schematic of a computer system 900, in accordance with an embodiment of the present invention. The computer system 900 (also referred to as the electronic system 900) as depicted can embody a hermetic layer above a filler material and a die, according to any of the several disclosed embodiments and their equivalents as set forth in this disclosure. The computer system 900 may be a mobile device such as a netbook computer. The computer system 900 may be a mobile device such as a wireless smart phone. The computer system 900 may be a desktop computer. The computer system 900 may be a hand-held reader. The computer system 900 may be a server system. The computer system 900 may be a supercomputer or high-performance computing system.

In an embodiment, the electronic system 900 is a computer system that includes a system bus 920 to electrically couple the various components of the electronic system 900. The system bus 920 is a single bus or any combination of busses according to various embodiments. The electronic system 900 includes a voltage source 930 that provides power to the integrated circuit 910. In some embodiments, the voltage source 930 supplies current to the integrated circuit 910 through the system bus 920.

The integrated circuit 910 is electrically coupled to the system bus 920 and includes any circuit, or combination of circuits according to an embodiment. In an embodiment, the integrated circuit 910 includes a processor 912 that can be of any type. As used herein, the processor 912 may mean any type of circuit such as, but not limited to, a microprocessor, a microcontroller, a graphics processor, a digital signal processor, or another processor. In an embodiment, the processor 912 includes, or is coupled with, a hermetic layer above a die and filler material, as disclosed herein. In an embodiment, SRAM embodiments are found in memory caches of the processor. Other types of circuits that can be included in the integrated circuit 910 are a custom circuit or an application-specific integrated circuit (ASIC), such as a communications circuit 914 for use in wireless devices such as cellular telephones, smart phones, pagers, portable computers, two-way radios, and similar electronic systems, or a communications circuit for servers. In an embodiment, the integrated circuit 910 includes on-die memory 916 such as static random-access memory (SRAM). In an embodiment, the integrated circuit 910 includes embedded on-die memory 916 such as embedded dynamic random-access memory (eDRAM).

In an embodiment, the integrated circuit 910 is complemented with a subsequent integrated circuit 911. Useful embodiments include a dual processor 913 and a dual communications circuit 915 and dual on-die memory 917 such as SRAM. In an embodiment, the dual integrated circuit 910 includes embedded on-die memory 917 such as eDRAM.

In an embodiment, the electronic system 900 also includes an external memory 940 that in turn may include one or more memory elements suitable to the particular application, such as a main memory 942 in the form of RAM, one or more hard drives 944, and/or one or more drives that handle removable media 946, such as diskettes, compact disks (CDs), digital variable disks (DVDs), flash memory drives, and other removable media known in the art. The external memory 940 may also be embedded memory 948 such as the first die in a die stack, according to an embodiment.

In an embodiment, the electronic system 900 also includes a display device 950, an audio output 960. In an embodiment, the electronic system 900 includes an input device such as a controller 970 that may be a keyboard, mouse, trackball, game controller, microphone, voice-recognition device, or any other input device that inputs information into the electronic system 900. In an embodiment, an input device 970 is a camera. In an embodiment, an input device 970 is a digital sound recorder. In an embodiment, an input device 970 is a camera and a digital sound recorder.

As shown herein, the integrated circuit 910 can be implemented in a number of different embodiments, including a package substrate having a hermetic layer above a die and filler material, according to any of the several disclosed embodiments and their equivalents, an electronic system, a computer system, one or more methods of fabricating an integrated circuit, and one or more methods of fabricating an electronic assembly that includes a package substrate having a hermetic layer above a die and filler material, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a hermetic layer above a die and filler material embodiments and their equivalents. A foundation substrate may be included, as represented by the dashed line of FIG. 9. Passive devices may also be included, as is also depicted in FIG. 9.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

### EXAMPLES

The following paragraphs describe examples of various embodiments.
Example 1 is an apparatus comprising: a substrate; one or more dies on a surface of the substrate; and a layer that includes nitrogen on a surface of the one or more dies.
Example 2 includes the apparatus of example 1, further comprising a filler material that at least partially surrounds the one or more dies, wherein the layer that includes nitrogen is on the filler material.
Example 3 includes the apparatus of example 2, wherein at least a portion of the filler material immediately adjacent to the layer that includes nitrogen is not in a plane of the surface of the one or more dies.
Example 4 includes the apparatus of examples 2 or 3, wherein the filler material includes a selected one or more of: epoxy, silicon, or oxygen.
Example 5 includes the apparatus of examples 2, 3, or 4, wherein a composition of the layer that includes nitrogen comprises up to 3% oxygen in a cross-sectional area.
Example 6 includes the apparatus of examples 2, 3, 4, or 5, wherein the layer that includes nitrogen is a first layer; and further comprising a second layer on the first layer.
Example 7 includes the apparatus example 6, wherein the second layer includes a selected one or more of: oxygen or a nitrogen, and wherein the first layer forms a hermetic layer.
Example 8 includes apparatus of examples 2, 3, 4, 5, 6, or 7 wherein the layer that includes nitrogen further includes a nitride.
Example 9 includes apparatus of examples 2, 3, 4, 5, 6, 7, or 8, wherein the layer that includes nitrogen has a thickness ranging from 100 nm to 1 micrometer.
Example 10 includes the apparatus of examples 2, 3, 4, 5, 6, 7, 8, or 9, wherein the layer that includes nitrogen is deposited using a selected one or more of: physical vapor deposition (PVD), chemical vapor deposition (CVD), atomic layer deposition (ALD), or spin coating.
Example 11 includes the apparatus of examples 2, 3, 4, 5, 6, 7, 8, 9, or 10, wherein the substrate includes a base die.
Example 12 is a system comprising: a substrate; one or more dies on a surface of the substrate, wherein the one or more dies are electrically and physically coupled to the substrate; a filler material at least partially surrounding the one or more dies; a first layer that includes nitride on the one or more dies and on the filler material, wherein the first layer is a hermetic layer; and a second layer on the first layer.
Example 13 includes a system of example 12, wherein the first layer is direct bonded to the second layer.
Example 14 includes the system of examples 12 or 13, further comprising a third layer between the first layer and the second layer, wherein the second layer includes oxygen.
Example 15 includes a system of example 14, wherein the third layer is direct bonded to the second layer.
Example 16 includes a system of examples 12, 13, 14 or 15, wherein the substrate includes a die, and wherein the second layer includes a selected one of: an interposer, a silicon wafer, or glass.
Example 17 includes the system of examples 12, 13, 14, 15, or 16, wherein a composition of the first layer that includes nitrogen includes up to 3% oxygen in a cross-sectional area.
Example 18 is a method comprising: providing a substrate; providing one or more dies on the substrate; placing a filler material around at least a portion of the one or more dies; and placing a layer that includes nitride on the filler material and on the one or more dies.
Example 19 includes the method of example 18, wherein the layer that includes nitride is a first layer; and further comprising: placing a second layer on the first layer, wherein the first layer is a hermetic layer.
Example 20 includes the method of example 19, further comprising direct bonding a third layer on the second layer, wherein the second layer includes oxygen, and wherein the third layer includes a selected one of: an interposer, a silicon wafer, or glass.
Example 21 is an apparatus, comprising: a first die comprising through silicon vias (TSVs); a second die over the first die, the second die conductively coupled to the TSVs; a third die over the first die and adjacent to the second die, the third die conductively coupled to the TSVs; a mold material over the first die and between the second die and the third die; a first layer over the first die, the second die, and the mold material, wherein the first layer comprises primarily silicon and nitrogen; a second layer on the first layer, wherein the second layer comprises primarily silicon and oxygen; and a third layer on the second layer, wherein the third layer comprises primarily silicon and less than 5% nitrogen and/or oxygen.
Example 22 includes the apparatus of example 21, wherein at least a portion of a top of the mold material immediately adjacent to the first layer is not in a plane of a top surface of the second die or not in a plane of a top surface of the third die.
Example 23 includes the apparatus of example 22, wherein the at least a portion of the mold material immediately adjacent to the first layer is below the plane of the top surface of the second die or below the plane of the top surface of the third die.
Example 24 includes the apparatus of examples 22 or 23, wherein the mold material includes a selected one or more of: epoxy, silicon, or oxygen.
Example 25 includes the apparatus of examples 21, 22, 23, or 24, wherein a first percentage of nitrogen of a first cross-sectional area of the first layer is greater than a second percentage of nitrogen of a second cross-sectional area of the second layer.
Example 26 includes the apparatus of examples 21, 22, 23, 24, or 25, wherein the first layer is a hermetic layer.
Example 27 includes the apparatus of examples 21, 22, 23, 24, 25, or 26, wherein the first layer includes a glass material with an amorphous crystal structure.
Example 28 includes the apparatus of examples 21, 22, 23, 24, 25, 26, or 27, wherein the first layer further includes a nitride.
Example 29 includes the apparatus of examples 21, 22, 23, 24, 25, 26, 27, or 28, wherein the first layer has a thickness ranging from 100 nm to 1 micrometer.
Example 30 includes the apparatus of examples 21, 22, 23, 24, 25, 26, 27, 28, or 29, wherein the first layer is deposited using a selected one or more of: physical vapor deposition (PVD), chemical vapor deposition (CVD), atomic layer deposition (ALD), or spin coating.
Example 31 includes the apparatus of examples 21, 22, 23, 24, 25, 26, 27, 28, 29, or 30, wherein the second die or the third die is direct bonded to the first die.
Example 32 is a system comprising: a substrate; one or more dies on a surface of the substrate, wherein the one or more dies are electrically and physically coupled to the substrate; a mold material on the substrate at least partially surrounding the one or more dies; a first layer that includes nitride on the one or more dies and on the mold material, wherein the first layer is a hermetic layer; and a second layer on the first layer, wherein the second layer comprises primarily silicon and oxygen.
Example 33 includes the system of example 32, wherein the first layer is direct bonded to the second layer.
Example 34 includes the system of examples 32 or 33, further comprising a third layer on the second layer, wherein the third layer includes less than 5% nitrogen and/or oxygen.
Example 35 includes the system of example 34, wherein the third layer is direct bonded to the second layer.
Example 36 includes the system of examples 34 or 35, wherein the substrate includes a die, and wherein the third layer includes a selected one of: an interposer, a silicon wafer, or glass.
Example 37 includes the system of examples 32, 33, 34, 35, or 36, wherein at least a portion of a top of the mold material is below a plane of a top of one of the one or more dies.
Example 38 is a method comprising: providing a substrate; providing one or more dies on the substrate; placing a mold material around at least a portion of the one or more dies; and placing a layer that comprises primarily silicon and nitrogen on the mold material and on the one or more dies.
Example 39 includes the method of example 38, wherein the layer is a first layer; and further comprising: placing a second layer on the first layer, wherein the second layer comprises primarily silicon and oxygen.
Example 40 includes the method of example 39, further comprising placing a third layer on the second layer, wherein the third layer comprises primarily silicon and less than 5% nitrogen and/or oxygen.

What is claimed is:

1. An apparatus, comprising:
a first die comprising through silicon vias (TSVs);
a second die over the first die, the second die conductively coupled to the TSVs;
a third die over the first die and adjacent to the second die, the third die conductively coupled to the TSVs;
a mold material over the first die and between the second die and the third die;
a first layer over the first die, the second die, and the mold material, wherein the first layer comprises primarily silicon and nitrogen;
a second layer on the first layer, wherein the second layer comprises primarily silicon and oxygen; and
a third layer on the second layer, wherein the third layer comprises primarily silicon and less than 5% nitrogen and/or oxygen.

2. The apparatus of claim 1, wherein at least a portion of a top of the mold material immediately adjacent to the first layer is not in a plane of a top surface of the second die or not in a plane of a top surface of the third die.

3. The apparatus of claim 2, wherein the at least a portion of the mold material immediately adjacent to the first layer is below the plane of the top surface of the second die or below the plane of the top surface of the third die.

4. The apparatus of claim 2, wherein the mold material includes a selected one or more of: epoxy, silicon, or oxygen.

5. The apparatus of claim 1, wherein a first percentage of nitrogen of a first cross-sectional area of the first layer is greater than a second percentage of nitrogen of a second cross-sectional area of the second layer.

6. The apparatus of claim 1, wherein the first layer is a hermetic layer.

7. The apparatus of claim 1, wherein the first layer includes a glass material with an amorphous crystal structure.

8. The apparatus of claim 1, wherein the first layer further includes a nitride.

9. The apparatus of claim 1, wherein the first layer has a thickness ranging from 100 nm to 1 micrometer.

10. The apparatus of claim 1, wherein the first layer is deposited using a selected one or more of: physical vapor deposition (PVD), chemical vapor deposition (CVD), atomic layer deposition (ALD), or spin coating.

11. The apparatus of claim 1, wherein the second die or the third die is direct bonded to the first die.

12. A system comprising:
a substrate;
one or more dies on a surface of the substrate, wherein the one or more dies are electrically and physically coupled to the substrate;
a mold material on the substrate at least partially surrounding the one or more dies;
a first layer that includes nitride on the one or more dies and on the mold material, wherein the first layer is a hermetic layer; and
a second layer on the first layer, wherein the second layer comprises primarily silicon and oxygen.

13. The system of claim 12, wherein the first layer is direct bonded to the second layer.

14. The system of claim 12, further comprising a third layer on the second layer, wherein the third layer includes less than 5% nitrogen and/or oxygen.

15. The system of claim 14, wherein the third layer is direct bonded to the second layer.

16. The system of claim 14, wherein the substrate includes a die, and wherein the third layer includes a selected one of: an interposer, a silicon wafer, or glass.

17. The system of claim 12, wherein at least a portion of a top of the mold material is below a plane of a top of one of the one or more dies.

18. A method comprising:
providing a substrate;
providing one or more dies on the substrate;
placing a mold material around at least a portion of the one or more dies; and
placing a layer that comprises primarily silicon and nitrogen on the mold material and on the one or more dies.

19. The method of claim 18, wherein the layer is a first layer; and further comprising: placing a second layer on the first layer, wherein the second layer comprises primarily silicon and oxygen.

20. The method of claim 19, further comprising placing a third layer on the second layer, wherein the third layer comprises primarily silicon and less than 5% nitrogen and/or oxygen.
